(19) United States
(12) Patent Application Publication
(10) Pub. No.: US 2024/0192410 A1
(43) Pub. Date: Jun. 13, 2024

(54) MULTILAYER REFLECTOR TO SLOW RATE OF TEMPERATURE INCREASE IN COMPONENTS

(71) Applicants: The Boeing Company, Arlington, VA (US); CALIFORNIA INSTITUTE OF TECHNOLOGY, Pasadena, CA (US)

(72) Inventors: Leora Peltz, Pasadena, CA (US); Axel Scherer, Barnard, VT (US); Taeyoon Jeon, Pasadena, CA (US)

(21) Appl. No.: 18/300,145

(22) Filed: Apr. 13, 2023

Related U.S. Application Data
(60) Provisional application No. 63/387,206, filed on Dec. 13, 2022.

(51) Int. Cl. G02B 5/08; B64C 30/00; G02B 7/183; H05K 5/02

(52) U.S. Cl. CPC G02B 5/085; G02B 5/0883; G02B 7/183; H05K 5/0209; B64C 30/00

(57) ABSTRACT

One disclosed example provides a vehicle, comprising an outer shell defining an interior, a component located within the interior, and a multilayer reflector located between the outer shell of the vehicle and the component. The multilayer reflector comprises a plurality of alternating layers of a first material with a first refractive index and a second material with a second refractive index, the second refractive index being higher than the first refractive index.

### CROSS REFERENCE TO RELATED APPLICATIONS

This application claims priority to U.S. Provisional Patent Application No. 63/387,206, entitled MULTILAYER REFLECTOR TO SLOW RATE OF TEMPERATURE INCREASE IN ELECTRONIC COMPONENTS, filed Dec. 13, 2022, the entirety of which is hereby incorporated herein by reference for all purposes.

### BACKGROUND

Electronic components can be exposed to high temperatures in some use environments. For example, electronic components within a hypersonic vehicle can be exposed to high temperatures that arise from friction against a skin of the hypersonic vehicle during use. When the skin of the hypersonic vehicle is heated, the skin can transmit heat into an interior of the hypersonic vehicle. This heat can damage electronic components inside of the hypersonic vehicle.

Electronic components can be protected with phase change materials to maintain acceptable temperatures in high-temperature environments. However, phase change materials can be bulky and heavy.

### SUMMARY

Examples are disclosed that relate to the use of multilayer reflectors to help reduce a rate of temperature increase of a component. The disclosed examples can be used to help protect components in a variety of different use environments. Examples include vehicles, such as hypersonic vehicles.

One disclosed example provides a vehicle, comprising an outer shell defining an interior, a component located within the interior, and a multilayer reflector located between the outer shell of the vehicle and the component. The multilayer reflector comprises a plurality of alternating layers of a first material with a first refractive index and a second material with a second refractive index, the second refractive index being higher than the first refractive index.

Another disclosed example provides a component comprising a multilayer reflector. The multilayer reflector comprises a plurality of alternating layers of a first material with a first refractive index and a second material with a second refractive index. The second refractive index is higher than the first refractive index. The alternating layers comprise thicknesses selected to provide a peak reflectance at an infrared wavelength.

Another disclosed example provides a method comprising depositing, on an electronic component for a vehicle, a plurality of alternating layers of a first material with a first refractive index and a second material with a second refractive index to form a multilayer reflector. The second refractive index is higher than the first refractive index.

### BRIEF DESCRIPTION OF THE DRAWINGS

FIG. 1 schematically depicts an example hypersonic aircraft.

FIG. 2 schematically depicts an example container holding an electronic component.

FIG. 3 schematically illustrates an example multilayer reflector formed on a substrate.

FIG. 4 schematically illustrates an example multilayer reflector formed on a package for an electronic component.

FIG. 5 schematically illustrates an example multilayer reflector formed on a die of an electronic component.

FIG. 6 schematically illustrates an example multilayer reflector formed on a container holding an electronic component.

FIG. 7 shows a scanning electron microscope image of a Ge/BaF2 multilayer reflector along with a mirror transmission spectrum that shows a wavelength range over which the depicted multilayer reflector reflects light.

FIG. 8 depicts a flow diagram of an example method for depositing a multilayer reflector on an electronic component.

FIG. 9 schematically shows a schematic block depiction of a vehicle comprising a component protected by a multilayer reflector.

### DETAILED DESCRIPTION

Heat can be transmitted to components, such as electronic components, within vehicles through radiation, convection, and conduction. Each of these can contribute to the thermal load of a system. By surrounding an object of interest with mirrors that can reflect heat radiation, it is possible to reduce this thermal load. Often, this is done with simple metal layers that reflect light efficiently over wide spectral ranges. However, metal layers are generally also efficient conductors of heat, and it is often desirable to construct radiative reflectors that do not conduct. Moreover, it is often desirable to provide optical access to an object of interest through such “heat shields”, which is impossible when using metal layers.

Thus, examples are disclosed that relate to the use of multilayer reflectors to reflect blackbody radiation away from components. Multilayer reflectors comprise alternating layers of a higher refractive index material and a lower refractive index material. The terms “Bragg reflector” and “dielectric mirror” are also used sometimes to refer to multilayer reflectors. However, a multilayer reflector can also reflect wavelengths of light that do not strictly meet the Bragg condition—for example, a multilayer reflector can also reflect a range of wavelengths to either side of a Bragg wavelength. The Bragg wavelength is defined as the wavelength λ that satisfies nλ=2d sin θ, where n is the diffraction order, d is the thickness of layers in the multilayer reflector, and θ is the angle of incident light relative to the surface normal of the multilayer reflector. Further, in some examples a multilayer reflector can use material layers that are semiconductors, rather than dielectrics.

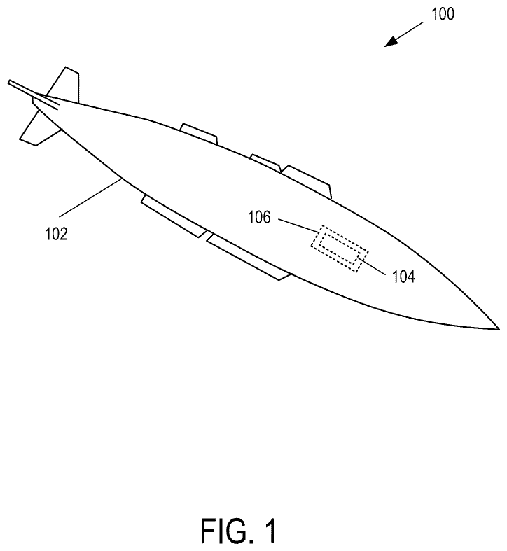

As previously mentioned, components in a hypersonic vehicle can be exposed to high temperatures during operation of the hypersonic vehicle. FIG. 1 schematically depicts an example hypersonic vehicle 100 in the form of a guided rocket. Hypersonic vehicle 100 comprises an outer shell 102 defining an interior. Hypersonic vehicle 100 further comprises a component 104 located within the interior. Component 104 can be configured as part of a guidance system, flight system, or other suitable system for operation of hypersonic vehicle 100. Hypersonic vehicle 100 further comprises a multilayer reflector 106 located between outer shell 102 and component 104. Multilayer reflector 106 comprises a plurality of alternating layers of a first material and a second material, as discussed in more detail below. Multilayer reflector 106 is configured to provide a peak reflectance at an infrared wavelength, and thus reflects radiant heat away from component 104. This can help to slow a rate of temperature increase in component 104, over selected wavelength ranges. The multilayer reflector 106 can be configured to protect electronics from high-temperature environments for a desired period of time, such as for a period of hours. While discussed herein in the context of a guided rocket, a multilayer reflector may be used to protect components in other suitable vehicles, both non-hypersonic and hypersonic. Examples include aircraft and spacecraft.

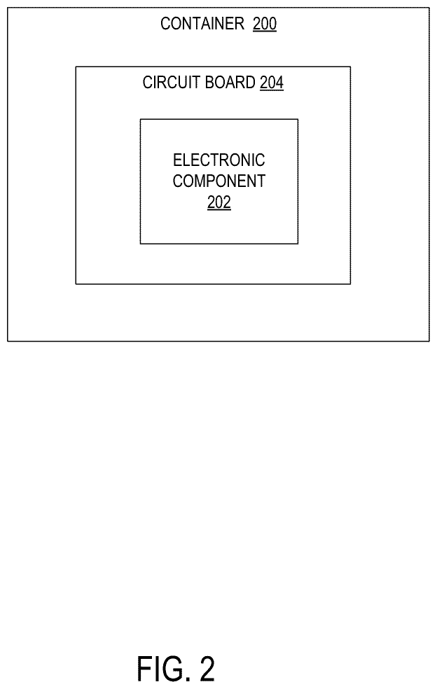

FIG. 2 depicts a block diagram of an example container 200. Container 200 can be for use in a hypersonic aircraft or other vehicle in which the container 200 may be exposed to a high-temperature environment. Container 200 holds an electronic component 202 mounted on a circuit board 204. In other examples, container 200 can hold more than one circuit board 204 and/or electronic component 202. In other examples, a vehicle may omit such a container for holding electronic components.

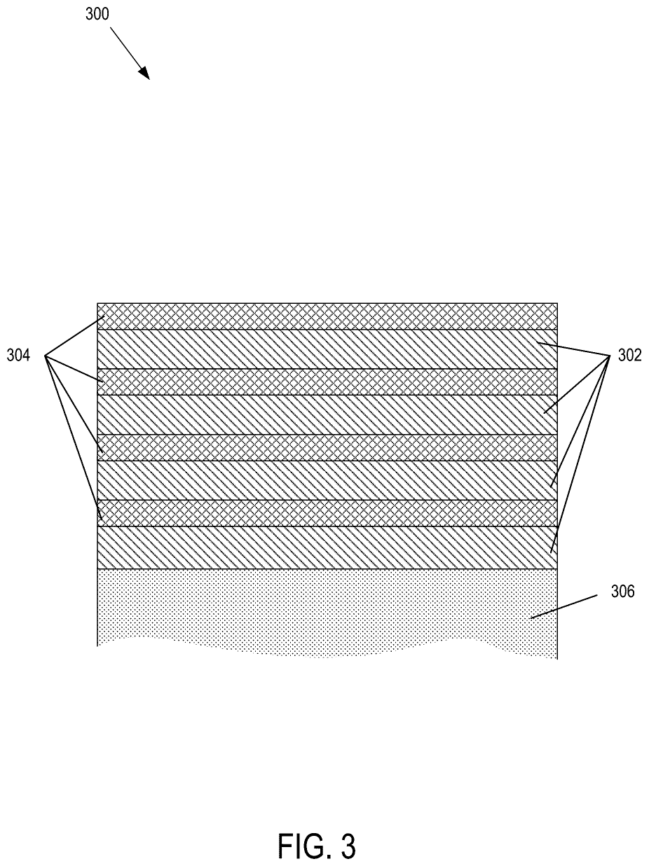

FIG. 3 schematically illustrates an example multilayer reflector 300 that can be formed on a component. Multilayer reflector 300 is an example of multilayer reflector 106. Multilayer reflector 300 comprises a plurality of alternating layers of a first material 302 with a first refractive index and a second material 304 with a second refractive index. The second refractive index is higher than the first refractive index. As shown, multilayer reflector 300 is formed on a substrate 306. Substrate 306 can be a surface of an electronic or other thermally sensitive component, or other suitable surface between the component and an outer skin of a vehicle.

In some examples, multilayer reflector 300 comprises alternating layers of semiconductors with high refractive index and fluoride layers with low refractive index. Multilayer reflectors made with fluoride layers can reflect infrared light while conducting little to no heat. As the temperature of blackbody emitters (e.g., an inner surface of a hypersonic vehicle outer shell) determines the emission spectrum, multilayer reflector 300 may be designed for specific wavelength ranges. For example, blackbody emissions at 8 microns corresponds to approximately 100 degrees Celsius. Multilayer mirrors are often designed so that the individual layer thicknesses are a quarter of the target wavelength. This quarter-wave mirror typically functions over a limited wavelength range, and becomes less efficient when the wavelength deviates from the quarter wavelength design. The spectral range over which the dielectric mirror provides high reflectivity is defined as the free spectral range. This free spectral range depends on the refractive index contrast between the high and low index layers defining the mirror. Multilayer reflectors constructed by depositing alternating layers of semiconductors with high refractive index and fluoride layers with low refractive index can reflect infrared (blackbody) radiation throughout a large fraction of the infrared wavelength range. For example, such multilayer reflectors can be tuned to cover broad wavelength ranges within 1.1 micrometers (below which the semiconductors absorb light) and 14 micrometers (above which the fluorides absorb light). In some such examples, the multilayer reflector comprises alternating germanium and barium fluoride layers.

As mentioned above, high contrast multilayer reflectors comprising fluoride layers have the interesting attribute that they reflect light while conducting little to no heat, and can be designed to reflect large wavelength ranges that target blackbody emission windows. As the temperature of the blackbody emitter determines the emission spectrum, it is possible to design multilayer reflector 300 for specific wavelength ranges. The multilayer structure can also be designed to provide “spectral windows” within which the mirror is transparent. Further, additional multilayer reflectors tuned to different wavelength ranges can be stacked onto multilayer reflector 300 to increase a spectral bandwidth of the overall reflective structure. Additionally, the thickness of layers of multilayer reflector 300 can vary through a depth of multilayer reflector 300 to broaden a peak of the reflectivity range of multilayer reflector 300, although with some decrease in peak intensity. It will be understood that the specific configuration of layers of FIG. 3 is schematic illustrative, and that in other examples, a multilayer reflector can comprise other configurations, such as different numbers of layers.

As previously mentioned, a multilayer reflector can be used to reflect blackbody emissions from nearby blackbody radiation sources. In this manner, the multilayer reflector acts as a heat shield, protecting electronics (including opto-electronics) from the infrared radiation. This can reduce a rate at which the electronics increase in temperature in a high-temperature environment. In various examples, the multilayer reflector can be applied to different surfaces between an electronic device and an outer skin of a vehicle.

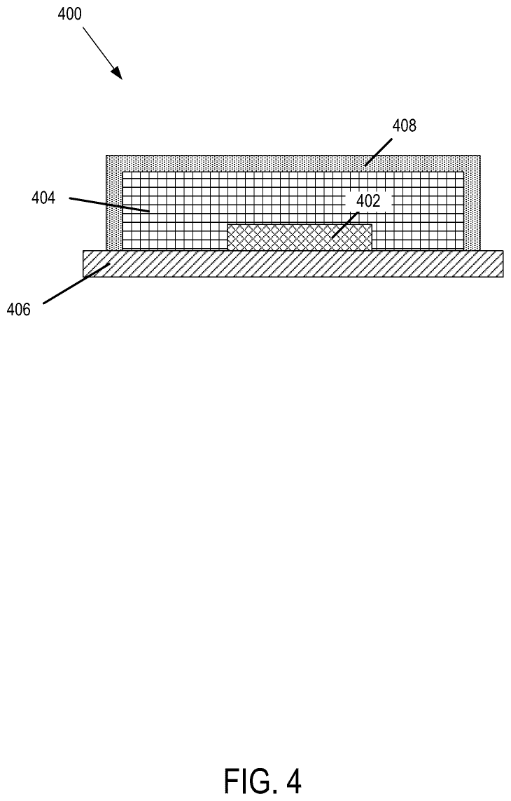

FIG. 4 schematically depicts an example electronic component 400 comprising a die 402 within a package 404. Die 402 can comprise a semiconductor die, and package 404 can be configured as an integrated circuit package, for example. As shown, die 402 and package 404 are placed on a circuit board 406. Further, a multilayer reflector 408 is formed on package 404 to protect an integrated circuit on die 402 from heat. Any suitable electronic component can be protected using a multilayer reflector according to the present disclosure. Examples include logic components, memory components, electromechanical components, optoelectronic components, and sensors.

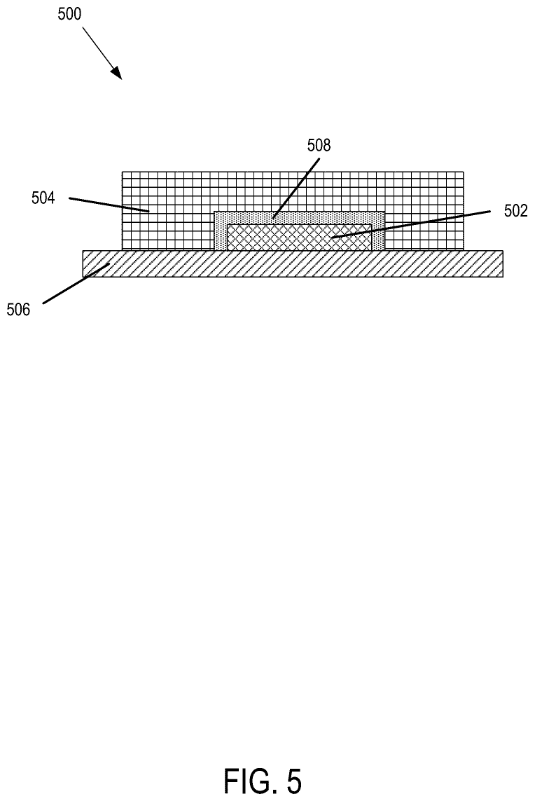

FIG. 5 schematically depicts another example electronic component 500. Similar to electronic component 400, electronic component comprises a die 502, a package 504, and a circuit board 506. However, in FIG. 5, a multilayer reflector 508 is formed on die 502, rather than on package 504, to protect an integrated circuit on die 502 from heat. In some examples, both a die and package can comprise multilayer reflectors.

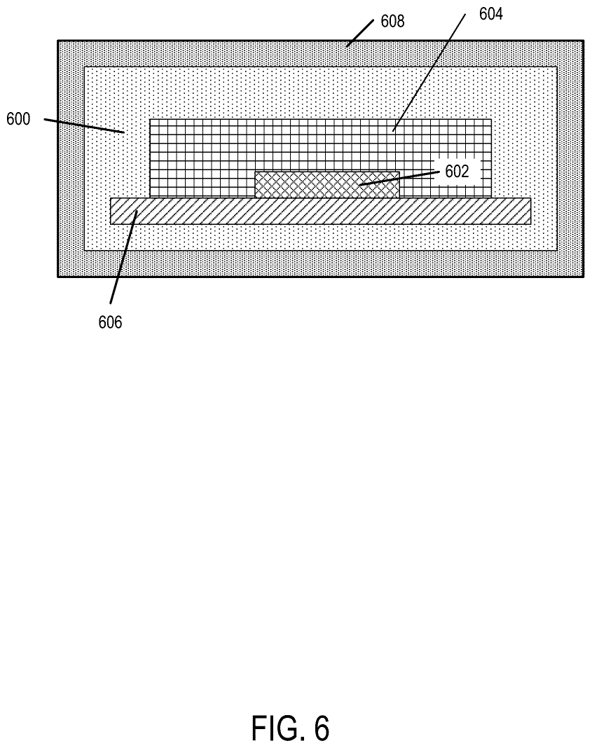

FIG. 6 schematically depicts an example container 600 holding an electronic component. The electronic component comprises a die 602 contained within a package 604. Further, die 602 and package are located on a circuit board 606. A multilayer reflector 608 is formed on container 600 to protect an integrated circuit on the die 602 from heat. In some examples, multilayer reflectors can be formed on any combination of two or more of a die, a package, and a container for an electronic device. Alternatively or additionally, in other examples, a multilayer reflector can be formed on any other suitable structure or structures located between an outer skin and an electronic device of a vehicle.

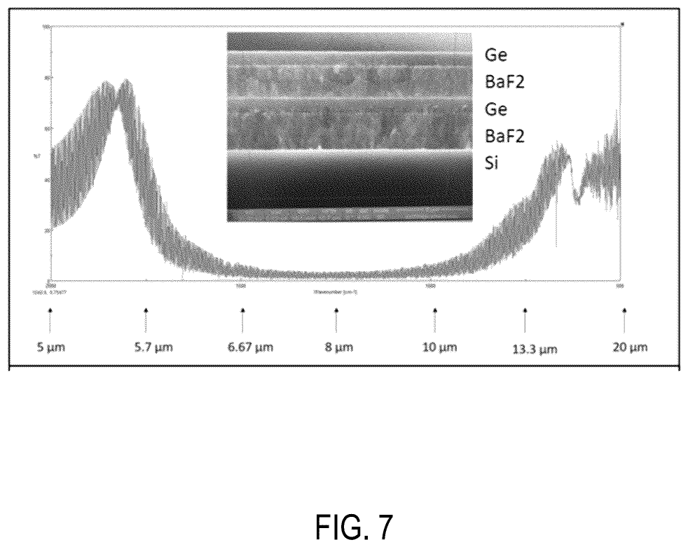

FIG. 7 shows a scanning electron microscope image of a germanium/barium fluoride (Ge/BaF₂) multilayer reflector along with mirror transmission spectrum that shows the wavelength range over which the depicted multilayer reflector reflects light. The depicted multilayer reflector is constructed from two pairs of BaF2/Ge pairs on a silicon substrate to provide a maximum reflectivity of around 98% at 8 micrometers. This maximum mirror reflectivity was designed to reflect 8 micrometer light, but reflects in the range from 6 to 11 micrometers, which corresponds to its free spectral range. The blackbody emission at 8 microns corresponds to approximately 100 degrees Celsius. When designed for shorter wavelength, this mirror structure can reflect radiation from higher temperature blackbody emitters, targeting anywhere from 100 degrees Celsius to 1,000 degrees Celsius. The thicknesses of the layers are then chosen to correspond to Wien's law prediction of the maximum in emission when designing the reflector. Wien's law can be expressed by λₚₑₐₖ=b/T, where b is Wein's displacement constant (with an approximate value of 2898 microns Kelvin), and T is the absolute temperature. While disclosed herein in the context of a barium fluoride/germanium multilayer reflector, in other examples any other suitable materials can be used.

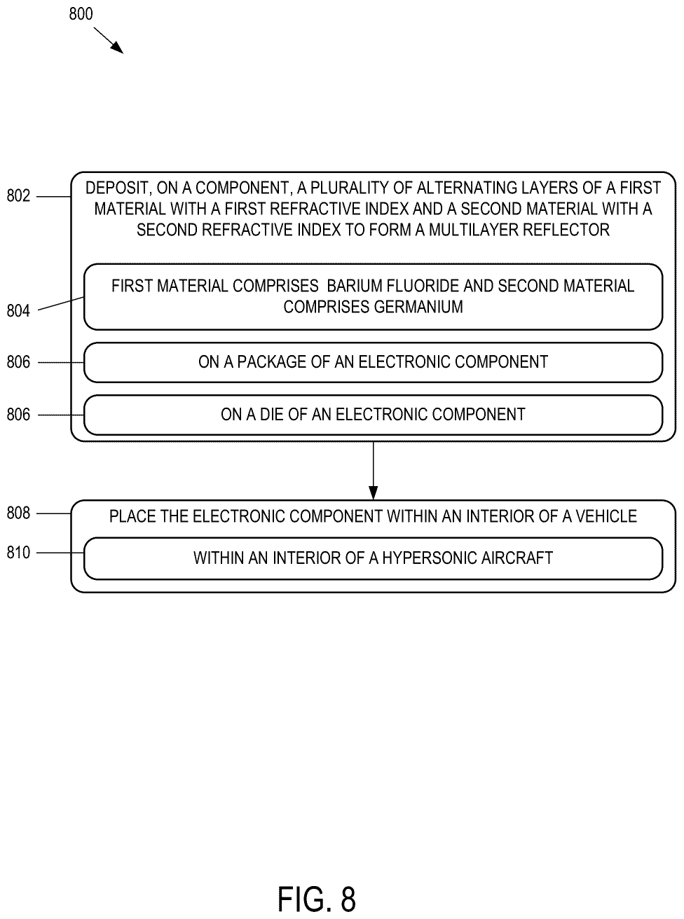

FIG. 8 depicts a flow diagram of an example method 800 for forming a multilayer reflector on a component. Method 800 may be used to form any multilayer reflector disclosed herein. Method 800 comprises, at 802, depositing, on a component, a plurality of alternating layers of a first material with a first refractive index and a second material with a second refractive index to form a multilayer reflector. The second refractive index is higher than the first refractive index. In the depicted example, the first material comprises barium fluoride, and the second material comprises germanium, as indicated at 804. In other examples, other suitable materials can be used. The layers forming the multilayer reflector can be deposited in any suitable manner. In the specific example of barium fluoride/germanium layers, the barium fluoride layers can be deposited by sputtering, laser ablation, or other physical vapor deposition methods. Further, the germanium layers also can be deposited by physical vapor deposition (sputtering, laser ablation, etc.), by chemical vapor deposition or atomic layer deposition, as further examples.

In some examples, the plurality of alternating layers of the first material of the first refractive index and the second material of the second refractive index are deposited on a package of an electronic component, as indicated at 806. In other examples, the plurality of alternating layers may be deposited on a die of an electronic component 807. In other examples, the plurality of alternating layers can be deposited on a container for holding an electronic component. In further examples, the plurality of alternating layers can be deposited on any other suitable surface configured to be positioned between an outer skin of a vehicle and a thermally-sensitive component. Method 800 further comprises, at 808, placing the component within an interior of a vehicle. In some examples, the vehicle is configured as a hypersonic aircraft, as indicated at 810. In such a manner, the multilayer reflector reflects blackbody radiation away from the component during operation of the hypersonic aircraft. In other examples, the vehicle can have any other suitable configuration than a hypersonic aircraft.

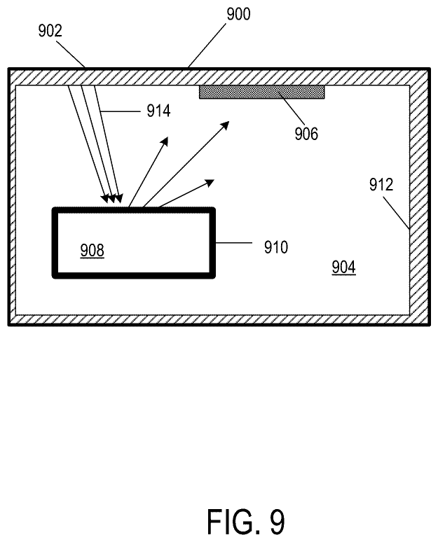

In some examples, a multilayer reflector can be positioned to reflect infrared light from a hotter source location to a cooler destination location. FIG. 9 schematically depicts a block diagram of an example vehicle 900. Vehicle 900 can be any suitable vehicle, including the examples given above. Vehicle 900 comprises an outer shell 902 defining an interior 904, and a heatsink 906 configured to remove heat from interior 904. Vehicle 900 further comprises a component 908 located within interior 904. Component 908 can represent an electronic component or other thermally sensitive component(s). A multilayer reflector 910 is formed on component 908. The individual layers of multilayer reflector 910 are omitted from FIG. 9 for clarity. Multilayer reflector 910 can be formed on a die or package of an electronic component, a container holding the electronic component, or other suitable surfaces between thermally sensitive components and outer shell 902. In some examples, multilayer reflectors can be located on two or more surfaces between the thermally sensitive components and outer shell 902.

During operation of vehicle 900, outer shell 902 may have a first, higher temperature (e.g., around 800 Celsius). Some of this heat is transferred to an inside structure 912. Inside structure 912 may have a second temperature (e.g., around 500 Celsius). Multilayer reflector 910 reflects blackbody radiation 914 from inside structure 912 towards heatsink 906, which has a third, cooler temperature. Then heatsink 906 transfers heat from the reflected blackbody radiation for dissipation from vehicle 900. In such a manner, a rate of temperature increase of component 908 can be slowed.

It will be understood that the configurations and/or approaches described herein are exemplary in nature, and that these specific embodiments or examples are not to be considered in a limiting sense, because numerous variations are possible. The subject matter of the present disclosure includes all novel and non-obvious combinations and sub-combinations of the various processes, systems and configurations, and other features, functions, acts, and/or properties disclosed herein, as well as any and all equivalents thereof.

The subject matter of the present disclosure includes all novel and non-obvious combinations and sub-combinations of the various processes, systems and configurations, and other features, functions, acts, and/or properties disclosed herein, as well as any and all equivalents thereof.

Further, the disclosure comprises configurations according to the following clauses.

Clause 1. A vehicle, comprising: an outer shell defining an interior; a component located within the interior; and a multilayer reflector located between the outer shell of the vehicle and the component, the multilayer reflector comprising a plurality of alternating layers of a first material with a first refractive index and a second material with a second refractive index, the second refractive index being higher than the first refractive index.

Clause 2. The vehicle of clause 1, wherein the vehicle is a hypersonic vehicle.

Clause 3. The vehicle of clause 2, wherein the hypersonic vehicle is an aircraft.

Clause 4. The vehicle of clause 1, wherein the first material is barium fluoride and the second material is germanium.

Clause 5. The vehicle of clause 1, wherein thicknesses of layers of the plurality of alternating layers vary through a depth of the multilayer reflector.

Clause 6. The vehicle of clause 1, wherein the component comprises an electronic component, and wherein the multilayer reflector is formed on a package for the electronic component.

Clause 7. The vehicle of clause 1, wherein the component comprises an electronic component, and wherein the multilayer reflector is formed on a die contained within a package for the electronic component.

Clause 8. The vehicle of clause 1, wherein the component comprises an electronic component, and wherein the multilayer reflector is formed on a container holding the electronic component.

Clause 9. The vehicle of clause 1, wherein the plurality of alternating layers of the multilayer reflector comprise thicknesses selected to provide a peak reflectance at an infrared wavelength.

Clause 10. The vehicle of clause 1, wherein the multilayer reflector is positioned to reflect infrared light from a hotter source location to a cooler destination location.

Clause 11. An electronic component, comprising: a multilayer reflector comprising a plurality of alternating layers of a first material with a first refractive index and a second material with a second refractive index, the second refractive index being higher than the first refractive index, wherein the alternating layers comprise thicknesses selected to provide a peak reflectance at an infrared wavelength.

Clause 12. The component of clause 11, wherein the component comprises an electronic component, and wherein the multilayer reflector is formed on a package of the electronic component.

Clause 13. The component of clause 11, wherein the component comprises an electronic component, and wherein the multilayer reflector is formed on a die contained within a package of the electronic component.

Clause 14. The component of clause 11, wherein the first material is barium fluoride, and the second material is germanium.

Clause 15. The component of clause 11, wherein thicknesses of layers of the plurality of alternating layers vary through a depth of the multilayer reflector.

Clause 16. The component of clause 11, wherein the component is a hypersonic aircraft.

Clause 17. A method, comprising: depositing, on an electronic component for a vehicle, a plurality of alternating layers of a first material with a first refractive index and a second material with a second refractive index to form a multilayer reflector, the second refractive index being higher than the first refractive index.

Clause 18. The method of clause 17, wherein the plurality of alternating layers of the material of the first refractive index and the material of the second refractive index are deposited on a package of the electronic component.

Clause 19. The method of clause 17, wherein the first material comprises barium fluoride, and the second material comprises germanium.

Clause 20. The method of clause 17, further comprising placing the component within an interior of a hypersonic aircraft.

1. A vehicle, comprising:
an outer shell defining an interior;
a component located within the interior; and
a multilayer reflector located between the outer shell of the vehicle and the component, the multilayer reflector comprising a plurality of alternating layers of a first material with a first refractive index and a second material with a second refractive index, the second refractive index being higher than the first refractive index.

2. The vehicle of claim 1, wherein the vehicle is a hypersonic vehicle.

3. The vehicle of claim 2, wherein the hypersonic vehicle is an aircraft.

4. The vehicle of claim 1, wherein the first material is barium fluoride and the second material is germanium.

5. The vehicle of claim 1, wherein thicknesses of layers of the plurality of alternating layers vary through a depth of the multilayer reflector.

6. The vehicle of claim 1, wherein the component comprises an electronic component, and wherein the multilayer reflector is formed on a package for the electronic component.

7. The vehicle of claim 1, wherein the component comprises an electronic component, and wherein the multilayer reflector is formed on a die contained within a package for the electronic component.

8. The vehicle of claim 1, wherein the component comprises an electronic component, and wherein the multilayer reflector is formed on a container holding the electronic component.

9. The vehicle of claim 1, wherein the plurality of alternating layers of the multilayer reflector comprise thicknesses selected to provide a peak reflectance at an infrared wavelength.

10. The vehicle of claim 1, wherein the multilayer reflector is positioned to reflect infrared light from a hotter source location to a cooler destination location.

11. An electronic component, comprising:
a multilayer reflector comprising a plurality of alternating layers of a first material with a first refractive index and a second material with a second refractive index, the second refractive index being higher than the first refractive index, wherein the alternating layers comprise thicknesses selected to provide a peak reflectance at an infrared wavelength.

12. The component of claim 11, wherein the component comprises an electronic component, and wherein the multilayer reflector is formed on a package of the electronic component.

13. The component of claim 11, wherein the component comprises an electronic component, and wherein the multilayer reflector is formed on a die contained within a package of the electronic component.

14. The component of claim 11, wherein the first material is barium fluoride, and the second material is germanium.

15. The component of claim 11, wherein thicknesses of layers of the plurality of alternating layers vary through a depth of the multilayer reflector.

16. The component of claim 11, wherein the component is a hypersonic aircraft.

17. A method, comprising:
depositing, on an electronic component for a vehicle, a plurality of alternating layers of a first material with a first refractive index and a second material with a second refractive index to form a multilayer reflector, the second refractive index being higher than the first refractive index.

18. The method of claim 17, wherein the plurality of alternating layers of the material of the first refractive index and the material of the second refractive index are deposited on a package of the electronic component.

19. The method of claim 17, wherein the first material comprises barium fluoride, and the second material comprises germanium.

20. The method of claim 17, further comprising placing the component within an interior of a hypersonic aircraft.
